(19) United States
(12) Patent Application Publication
(10) Pub. No.: US 2024/0321660 A1
(43) Pub. Date: Sep. 26, 2024

(54) STITCHED GUARD RINGS WITH OVERLAY ERROR RESILIENCY

(71) Applicant: Intel Corporation, Santa Clara, CA (US)

(72) Inventor: Shakul Tandon, Portland, OR (US)

(73) Assignee: Intel Corporation, Santa Clara, CA (US)

(21) Appl. No.: 18/188,577

(22) Filed: Mar. 23, 2023

(51) Int. Cl. H01L 23/31; H01L 21/56; H01L 23/00; H01L 23/498; H01L 23/532; H01L 25/065; H01L 25/10

(52) U.S. Cl. CPC H01L 23/3107; H01L 21/56; H01L 23/49827; H01L 23/53214; H01L 23/53228; H01L 23/53242; H01L 23/53257; H01L 24/16; H01L 25/0652; H01L 25/105; H01L 2224/16145; H01L 2224/16227; H01L 2224/16235; H01L 2924/182

(57) ABSTRACT

Embodiments of semiconductor devices with stitched guard rings, along with methods and lithographic reticles for forming the same, are disclosed herein. In one example, a semiconductor die includes a substrate with integrated circuitry, and a guard ring surrounding the integrated circuitry. The guard ring includes traces arranged in a pattern of lines and rungs, where the lines extend around the integrated circuitry and the rungs extend crosswise between at least some of the lines.

### BACKGROUND

Hermetic guard rings are used to protect semiconductor devices from the surrounding environment, including the infiltration of moisture, unwanted current flow, and so forth. In some cases, a hermetic guard ring may be fabricated on a semiconductor device that is larger than the maximum field size supported by the lithography system. As a result, the guard ring may be fabricated using reticle stitching, where different portions of the guard ring are printed using different reticles in adjacent fields of the wafer. Each portion of the guard ring must be precisely aligned to maintain continuity across stitched fields and prevent the hermeticity of the guard ring from breaking. Due to limitations of lithography technology, however, there is generally some degree of misalignment between features printed by different reticles. In some cases, these alignment errors may result in a gap between different portions of the guard ring, which breaks the hermetic barrier.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures.

FIG. 1 illustrates an example of a stitched guard ring on a die of a semiconductor wafer.

FIGS. 2A-B illustrate two-dimensional (2D) views of a semiconductor die with a stitched guard ring.

FIG. 3 illustrates a lithography reticle set for a stitched guard ring.

FIGS. 4A-D illustrate an interface of a stitched guard ring with orthogonal lines and rungs.

FIGS. 5A-B illustrate an interface of a stitched guard ring with orthogonal lines and rungs that overlap.

FIGS. 6A-B illustrate an interface of a stitched guard ring with orthogonal lines and rungs having patterned ends.

FIGS. 7A-H illustrate various examples of stitched lines with patterned interfaces.

FIG. 8 illustrates a flowchart for fabricating integrated circuits with stitched guard rings.

FIG. 9 is a cross-sectional side view of an integrated circuit device that may be included in a microelectronic assembly, in accordance with any of the embodiments disclosed herein.

FIG. 10 is a cross-sectional side view of an integrated circuit device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

As modern integrated circuits become increasingly complex, they may need to be fabricated on larger dies to accommodate the growth in complexity. However, the size of the dies is limited by the maximum field size that can be patterned on a wafer by lithographic reticles. A field is an area of a wafer patterned by a reticle, and the maximum field size is the maximum size of an area on the wafer that can be patterned by a single reticle. In current lithography technology, the maximum field size is 26 by 33 millimeters (mm) (858 mm²).

An individual die is typically fabricated using a set of reticles to sequentially pattern features on an area or “field” of a wafer to form the requisite circuitry. Each reticle, which is also referred to as a mask, contains a single pattern, and when stacked together, the patterns in a set of reticles collectively form the requisite components of an integrated circuit, such as resistors, capacitors, transistors, signal lines, and so forth.

Each field on the wafer is typically used to fabricate one or more completed dies. For example, in standard processing, the features of an individual die are typically fabricated within a single field on the wafer, which means the size of the die must be less than or equal to the maximum field size.

Due to this limitation, dies that are larger than the maximum field size can only be fabricated by “stitching” together multiple adjacent reticle fields on the wafer, which is referred to as reticle stitching. In reticle stitching, a feature that spans multiple fields of a wafer is formed piecemeal by stitching together portions of the feature formed by different reticles (or different regions of the same reticle) in adjacent fields. The reticles are aligned so that the respective portions of the feature adjoin at the stitch, which is the boundary between the adjacent fields.

As an example, a metal line (e.g., a signal line or conductive trace) that extends across two adjacent fields may be generated by sequentially exposing two different reticles over the respective fields, where each reticle forms a different portion of the line, such that a portion of the line from the first reticle and a portion of the line from the second reticle are adjoined at the stitch.

Stitched features must be precisely aligned to maintain continuity across fields and ensure proper functioning of the circuitry. Due to limitations of lithography technology, however, there is generally some degree of misalignment between different portions of a stitched feature. For example, the exposure of each reticle has a certain placement error (e.g., mask registration error), and local reticle/wafer distortions may also cause portions of features to misalign. In some cases, these errors can be additive, and the combined error of multiple reticles may result in an overlap, gap, or other misalignment between different portions of a stitched feature. These patterning errors can cause high resistance, disconnects, and other defects in stitched features.

Reticle stitching can be particularly challenging for certain types of features, such as hermetic barriers or guard rings that are used to protect semiconductor devices from the surrounding environment. For example, a hermetic guard ring is a protective barrier that protects the active components of a semiconductor device from infiltration of moisture and other contaminants, unwanted current flow, and so forth.

A guard ring is typically made of a thin strip of conductive material that surrounds the active components of a semiconductor device. On a typical chip fabricated within a single reticle field (e.g., without reticle stitching), a guard ring is printed by a single reticle/mask patterned with a continuous ring of lines around the active region of the die, which is subsequently filled with metal to form a hermetic seal.

However, on a chip stitched across multiple reticle fields, a guard ring is printed by multiple reticles/masks, each patterned with a different portion of the guard ring, which are exposed sequentially and joined at the stitch. If the portions of the guard ring printed by each reticle are misaligned (e.g., due to the placement/overlay errors noted above), there may be a gap between them that breaks the line continuity across the stitch zone, which breaks the hermeticity of the hermetic ring around the chip.

Accordingly, this disclosure presents embodiments of stitched guard rings designed with overlay error resiliency. These designs increase resilience to placement errors for hermetic guard rings that span reticle boundaries for in-fab reticle stitching. For example, these guard rings have patterned designs at the interface regions of stitched reticles, referred to as the stitch zone, where each part of a stitched guard ring from adjacent reticle fields meets. These guard rings use design features in the stitch zone that are more robust to misregistration between adjacent stitched reticle fields, such as patterns of orthogonal lines and rungs, patterned interfaces between connecting lines, and so forth.

These embodiments provide various advantages. Ensuring the integrity of a hermetic seal is crucial to providing a moisture barrier to the active die. These embodiments increase the robustness of stitched hermetic guard rings to misregistration between adjacent stitched reticle fields. These guard ring designs not only minimize the chance of the hermetic barrier breaking due to placement errors between adjacent stitched dies (e.g., by making the critical dimensions more resilient to these errors), but they also use a design approach where even if there is a break in stitch, the hermeticity of the guard ring is not compromised.

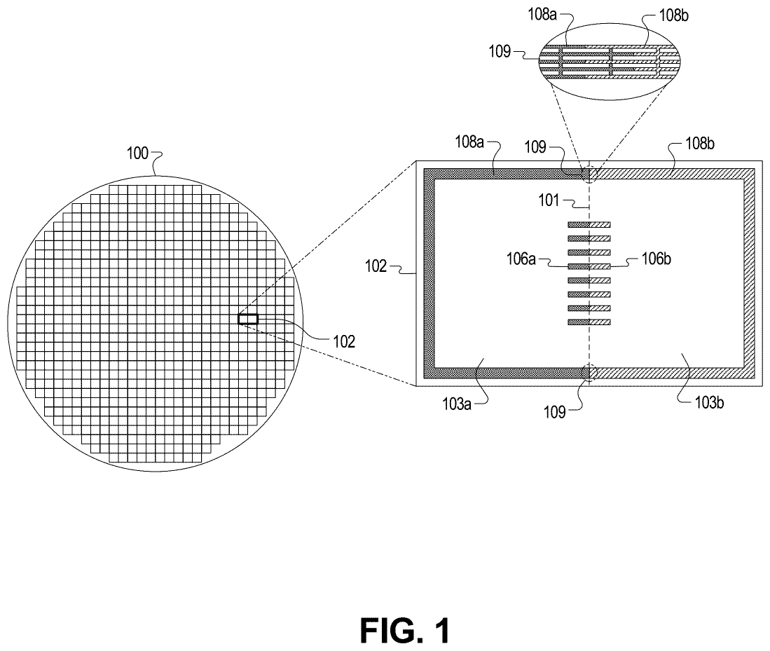

FIG. 1 illustrates an example of a stitched guard ring 108 on a die 102 of a semiconductor wafer 100. In the illustrated embodiment, wafer 100 includes a collection of integrated circuit (IC) dies 102. The layout for one of the dies 102 is shown, which is stitched across two adjacent fields 103a,b of the wafer 100 using reticle stitching. For example, two reticles are used to print the features at each stitched layer of the die 102, and the portions printed by each reticle are adjoined in the stitch zone 101. The stitch zone 101 is an area where features may be printed by either of the adjacent reticles due to a slight overlap between the adjacent reticle fields 103a,b.

In this example, two types of stitched features are shown: lines 106 and a hermetic guard ring 108. The lines 106 interconnect the circuitry in each stitched reticle field 103a,b, and the guard ring 108 protects the circuitry from the surrounding environment (e.g., moisture and other contaminants).

Each stitched feature is formed by two reticles that print different portions of the feature, which are joined in the stitch zone 101. For example, each line is formed by two reticles that print different portions 106a,b of the line in adjacent fields 103a,b on the wafer 100. The respective portions 106a,b printed by each reticle adjoin in the stitch zone 101 and collectively form a complete line 106. Similarly, the guard ring is formed by two reticles that print different portions 108a,b of the guard ring in adjacent fields 103a,b on the wafer 100. The respective portions 108a,b printed by each reticle adjoin in the stitch zone 101 and collectively form a complete guard ring 108.

In the illustrated example, the lines 106 and guard ring 108 are depicted at a high level for simplicity, but their actual designs are more complex. For example, the guard ring 108 is formed by a series of lines surrounding the active region of the die 102 (e.g., rather than a single line), with patterns at the stitch interfaces 109 that are more resilient to placement/overlay errors. The stitch interfaces 109 are the areas in the stitch zone 101 where different portions 108a,b of the guard ring are stitched together.

An example of the guard ring design at one of the stitch interfaces 109 is shown, which includes a series of parallel lines with orthogonal rungs extending between and across the lines. As described further throughout this disclosure, this design prevents a break in hermeticity even if there is a gap between the respective portions 108a,b of the guard ring due to overlay/placement errors during lithography processing.

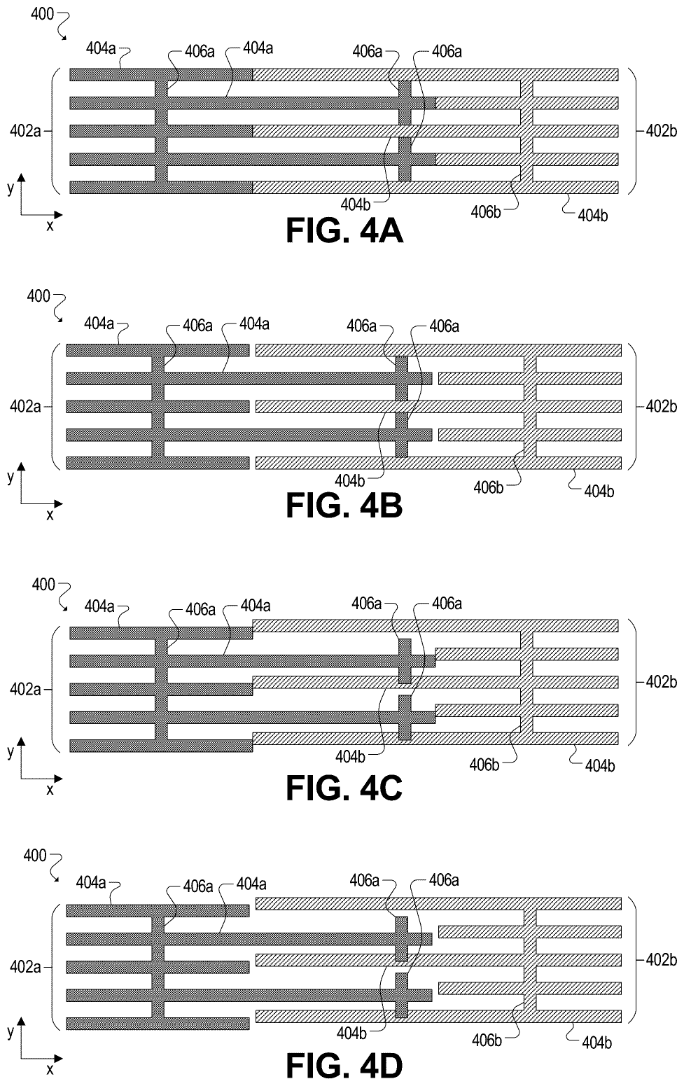

While the illustrated embodiment shows a die 102 stitched across two reticle fields 103a,b, other embodiments may be stitched across any number of reticle fields. Further, the guard ring 108 may be designed with a variety of different patterns other than those shown, including varying number of lines, line/rung patterns/interfaces, line/rung angles, line end patterns/interfaces, and so forth. In some embodiments, for example, the guard ring 108 may incorporate aspects of the designs shown in FIGS. 4-7.

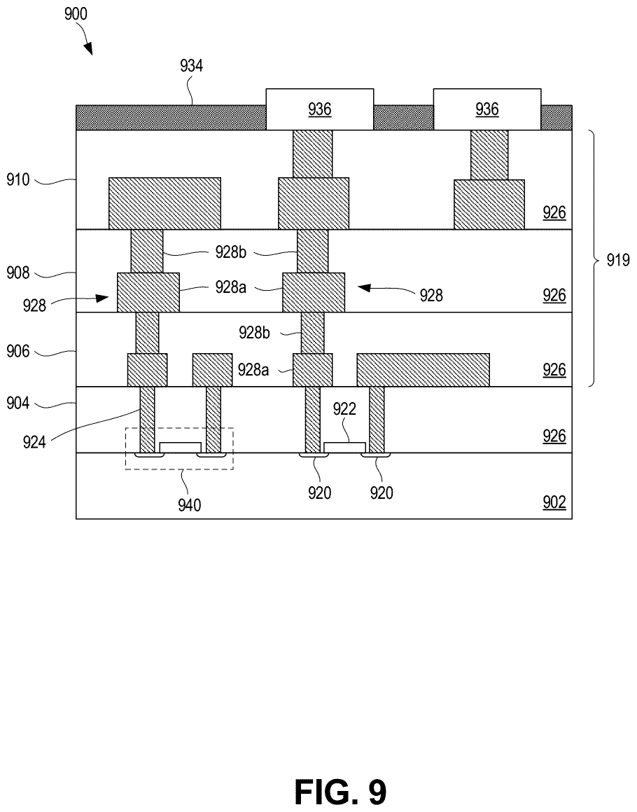

The wafer 100 may be composed of semiconductor material and may include one or more dies 102 having integrated circuit structures formed on a surface of the wafer 100. The individual dies 102 may be a repeating unit of an integrated circuit product that includes any suitable integrated circuit. After the fabrication of the semiconductor product is complete, the wafer 100 may undergo a singulation process in which the dies 102 are separated from one another to provide discrete “chips” of the integrated circuit product. Each die 102 may include one or more transistors (e.g., the transistors 940 of FIG. 9, discussed below), supporting circuitry to route electrical signals to the transistors, passive components (e.g., signal traces, resistors, capacitors, or inductors), and/or any other integrated circuit components.

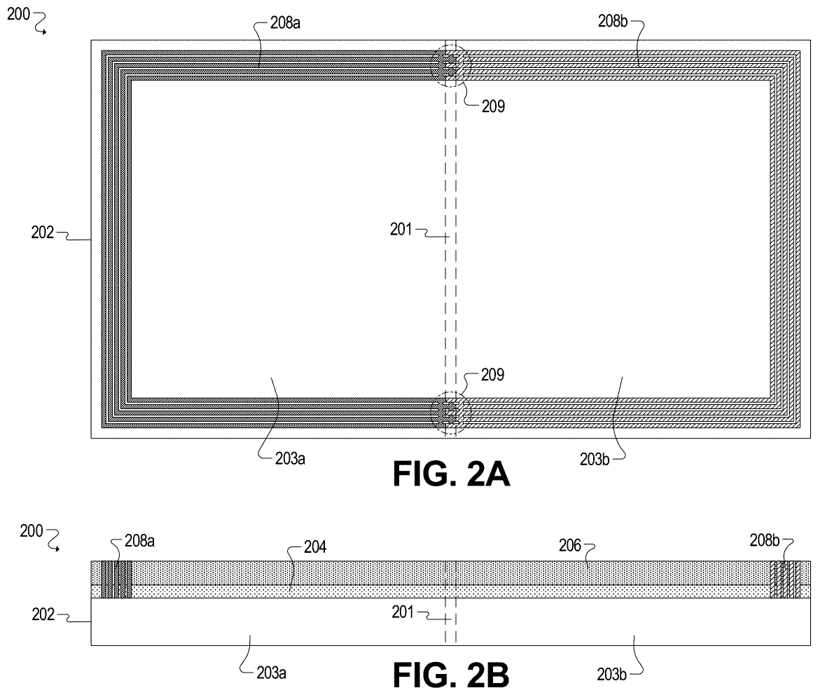

FIGS. 2A-B illustrate two-dimensional (2D) views of a semiconductor die 200 with a stitched guard ring in accordance with certain embodiments. In particular, FIG. 2A illustrates a plan view of die 200 and FIG. 2B illustrates a cross-section view of die 200.

In the illustrated embodiment, die 200 is stitched across two reticle fields 203a,b using reticle stitching, as described throughout this disclosure. The stitch zone 201 for the two reticle fields 203a,b is shown, which is an overlapping area between the reticle fields where they are stitched together. The stitch zone 201 may contain portions of features printed by either of the reticles (e.g., due to the overlap between the reticle fields).

The stitched die 200 is formed on a substrate 202 with one or more device layers 204 and one or more metallization/interconnect layers 206. The device layers 204 may include transistors, memory devices, capacitors, resistors, optoelectronic devices, switches, or any other active or passive electronic devices, or portions thereof. The metallization layers 206 may include conductive traces, such as vias and metal lines, to interconnect and provide access to devices in the device layers 204.

The stitched die 200 also includes a stitched hermetic guard ring 208. The guard ring is formed by two reticles that print different portions 208a,b of the guard ring in the respective fields 203a,b. The respective portions 208a,b printed by each reticle adjoin in the stitch zone 201 and collectively form a complete guard ring 208. Further, the guard ring 208 extends through the device and metallization layers 204, 206 and is in contact with the substrate 202.

In the illustrated embodiment, the guard ring 208 includes five metal lines surrounding the active circuitry in the die 200, with orthogonal rungs extending between and across the lines at the stitch interfaces 209. As described further throughout this disclosure, this design prevents a break in hermeticity even if there is a gap between the respective portions 208a,b of the guard ring due to overlay/placement errors during lithography processing. The patterns at the stitch interfaces 209 are described in further detail in connection with FIGS. 4-7.

In the guard ring embodiments shown throughout this disclosure, the lines and rungs are arranged orthogonally because lines on a reticle typically run horizontally or vertically. However, other arrangements are also possible as long as the lines surround the protected region and the rungs cross, intersect, or otherwise connect with the lines. For example, the rungs can connect with the lines at any angle, the angles can vary for different rungs, the rungs can be formed with curved lines instead of straight lines, and so forth. Similarly, the lines do not have to be parallel nor straight-they can be curved, non-parallel, irregularly spaced, and so forth.

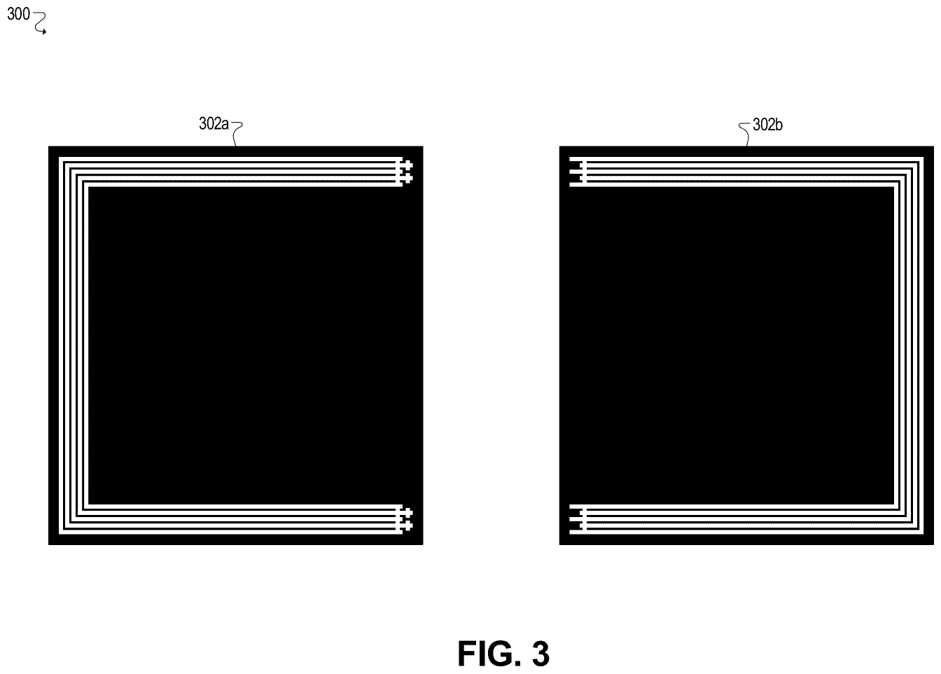

FIG. 3 illustrates a lithography reticle set 300 for a stitched guard ring. The reticle set 300 includes two reticles 302a,b, which are used to print different portions of a guard ring in adjacent fields on a wafer. The respective portions printed by each reticle 302a,b adjoin in the stitch zone and collectively form a complete guard ring. In the illustrated example, the reticle set 300 is designed to print the stitched guard ring 208 of FIGS. 2A-B. As a result, the reticles 302a,b are each patterned with corresponding portions 208a,b of guard ring 208.

Features such as guard rings, transistors, vias, and the like, are created on semiconductor wafers using photolithography processes. Creating features using lithography involves coating a wafer with a photosensitive resist, which is a light sensitive film that either becomes soluble or insoluble when exposed to light of a certain wavelength. The light of this wavelength is shone through a reticle, or mask, which contains a pattern for a desired feature to be transferred to the wafer. A reticle is a pattern transferring device, such as a glass or fused silica/quartz plate with opaque and transparent patterns on its surface. After the layer of photoresist has been exposed to light, the soluble portion can be removed, typically by immersion in a developer solution. Other processing techniques, such as etching or annealing, may then be performed to the underlying wafer that has been exposed as a result of the photolithography, thus transferring the pattern to the wafer.

In a reticle stitching context for a guard ring stitched across two reticle fields, the guard ring is generated by two different reticles exposed sequentially, such that a portion of the guard ring from the first reticle and a portion of the guard ring from the second reticle are adjoined at the stitch.

Herein, patterns, regions, features and the like are discussed with respect to reticle mask patterns and resultant patterns on the photoresist/wafer interchangeably. The pattern at the resist level is typically reduced (e.g., by 4×) from the reticle mask level and is invariably an imperfect reproduction. Herein, the discussed patterns, regions, or features may be at the reticle level (e.g., in the reticle mask) or at the resist/substrate level (e.g., either pre- or post-development).

FIGS. 4A-D illustrate an interface 400 of a stitched guard ring with orthogonal lines and rungs. Interface 400 depicts the patterns 402a,b printed by two adjacent reticles in the stitch zone of a guard ring (e.g., stitch zones 109, 209) where the respective patterns adjoin. Each pattern 402a,b includes orthogonal lines 404a,b and rungs 406a,b. For simplicity, only some lines 404a,b and rungs 406a,b are labeled with reference numerals. In this portion of the guard ring, the lines 404a,b extend horizontally and parallel to each other, the rungs 406a,b extend vertically between and/or across the lines 404a,b, and the lines 404a,b and rungs 406a,b are orthogonal to each other. Each pattern 402a,b includes one rung 406a,b that extends across all lines 404a,b in the respective pattern, and one of the patterns 402a also includes two shorter rungs 406a that each extend across one line 404a in that pattern but collectively extend across all lines 404a,b of the adjoined patterns 402a,b.

In some embodiments, the lines 404 may continue around the entire protected region of the guard ring (e.g., the active die circuitry), while the rungs 406 may be limited to the stitch zone where the respective patterns 402a,b formed by each reticle are susceptible to misalignment.

This is a more robust guard ring design, as it prevents a path for moisture intrusion even when there are gaps or openings due to pattern placement errors. In this design, the guard ring is patterned in the horizontal (x-axis) direction, creating a hermetic seal in the vertical (y-axis) direction. Further, some of the vertical rungs 406a patterned by one reticle connect with the horizontal lines 404b patterned by the adjacent reticle, which serves to block an open path for moisture intrusion. As a result, even with a gap due to overlay error in the x and/or y directions, the hermeticity is maintained.

For example, in FIG. 4A, the patterns 402a,b printed in each reticle field are perfectly aligned, and all lines 404a,b and rungs 406a,b in the respective patterns 402a,b are connected. As a result, the hermeticity is maintained.

In FIG. 4B, the patterns 402a,b printed in each reticle field are misaligned along the x axis, which results in a gap at the location of the join. However, even with the gap, the hermeticity is maintained due to the vertical rungs 406a,b.

In FIG. 4C, the patterns 402a,b printed in each reticle field are misaligned along the y axis, but no gap results from the misalignment. As a result, the hermeticity is maintained.

In FIG. 4D, the patterns 402a,b printed in each reticle field are misaligned along both the x and y axis, which results in a gap at the location of the join. However, even with the gap, the hermeticity is maintained, as there is no open path through the pattern of lines 404 and rungs 406 for moisture to penetrate.

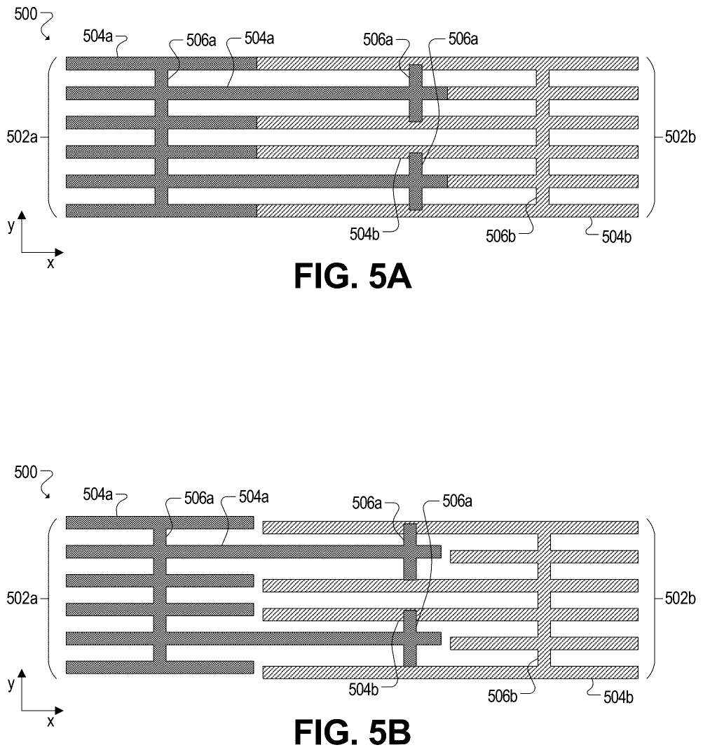

FIGS. 5A-B illustrate an interface 500 of a stitched guard ring with orthogonal lines and rungs that overlap. Interface 500 depicts the patterns 502a,b printed by two adjacent reticles in the stitch zone of a guard ring (e.g., stitch zones 109, 209) where the respective patterns adjoin. Each pattern 502a,b includes orthogonal lines 504a,b and rungs 506a,b. For simplicity, only some lines 504a,b and rungs 506a,b are labeled with reference numerals.

Interface 500 is a variant of interface 400 with extended rungs 506a on one of the patterns 502a to make it more robust to overlay error along the y axis. For example, the vertical rungs 506a patterned by one reticle are extended such that they overlap with the horizontal lines 504b patterned by the adjacent reticle to further reduce the number of opens caused by overlay error in the vertical (y-axis) direction.

In FIG. 5A, the patterns 502a,b printed in each reticle field are perfectly aligned, and all lines 504a,b and rungs 506a,b in the respective patterns 502a,b are connected. As a result, the hermeticity is maintained.

In FIG. 5B, the patterns 502a,b printed in each reticle field are misaligned along both the x and y axis, which results in a gap at the location of the join. However, even with this overlay error, the extended vertical rungs 506a still overlap with the horizontal lines 504b above and below them. As a result, the hermeticity is maintained even with the gap, as there is no open path through the pattern of lines 504 and rungs 506 that can be penetrated.

This design may require the hermetic ring to be wider, as more lines may be needed to accommodate the overlap. For example, while interface 400 only has five lines 404, interface 500 has six lines 504 to accommodate the overlap. As a result, the additional lines may widen the critical dimensions, which can be compensated for on the reticle by a reduction in the drawn mask critical dimensions.

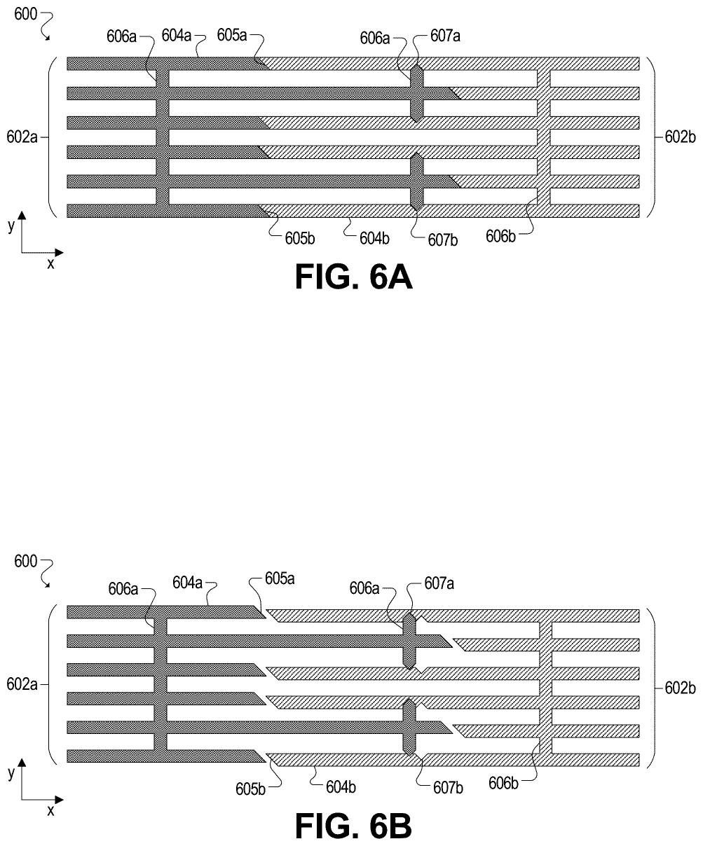

FIGS. 6A-B illustrate an interface 600 of a stitched guard ring with orthogonal lines and rungs having patterned ends. Interface 600 depicts the patterns 602a,b printed by two adjacent reticles in the stitch zone of a guard ring (e.g., stitch zones 109, 209) where the respective patterns adjoin. Each pattern 602a,b includes orthogonal lines 604a,b and rungs 606a,b with patterned line interfaces 605a,b and line/rung interfaces 607a,b. For simplicity, only some of the respective features are labeled with reference numerals.

Interface 600 is a variation of interfaces 400 and 500 with more complex line/rung ends that are less prone to opens from overlay errors, making it highly resilient to any negative impact on the hermeticity of the guard ring even when the patterns 602a,b printed by each reticle are misaligned. For example, in FIG. 6A, the patterns 602a,b printed in each reticle field are perfectly aligned, while in FIG. 6B, the patterns 602a,b are misaligned along both the x and y axis, which results in a gap at the location of the join. In both cases, the hermeticity of the guard ring is maintained.

The line ends 605a,b in the respective patterns 602a,b have complementary angles instead of straight edges, making them more robust to overlay errors. In addition, where the vertical rungs 606a in one pattern 602a overlap with the horizontal lines 604b in the other pattern 602b, their respective designs are modified to avoid any line bulge effect. For example, the rung ends 607a are patterned with an arrowhead shape, while the body of the lines are patterned with a complementary cavity 607b of the same shape that interfaces with the rung ends 607a.

These more complex line/rung ends further smoothen out overlay mismatches. For example, any overlap (or gap) is spread over a larger area, which smooths out regions of photoacid concentration perturbations. The end result is a more diffuse boundary.

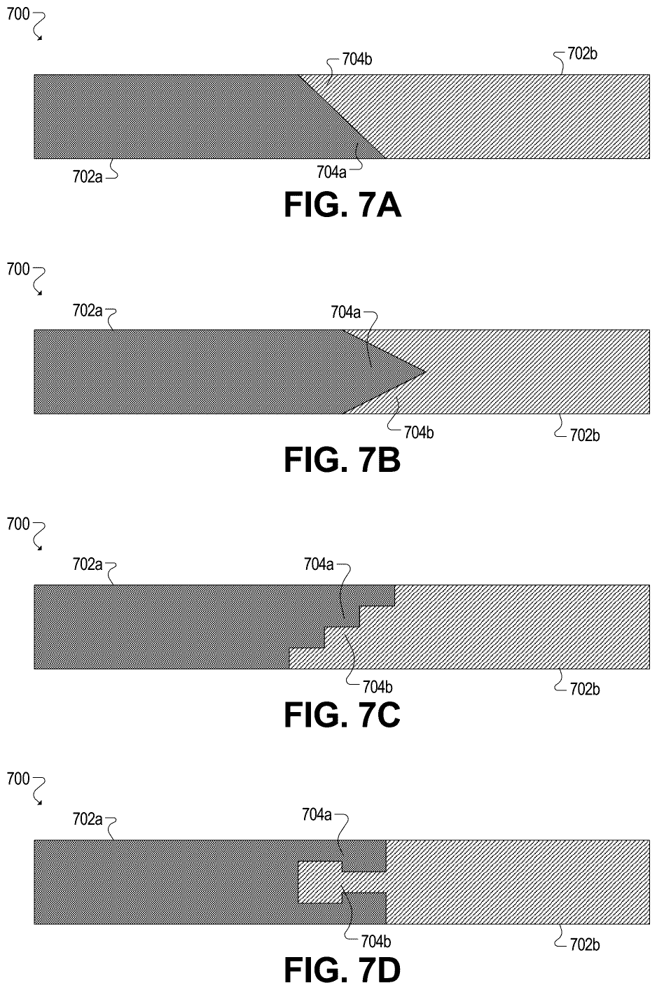

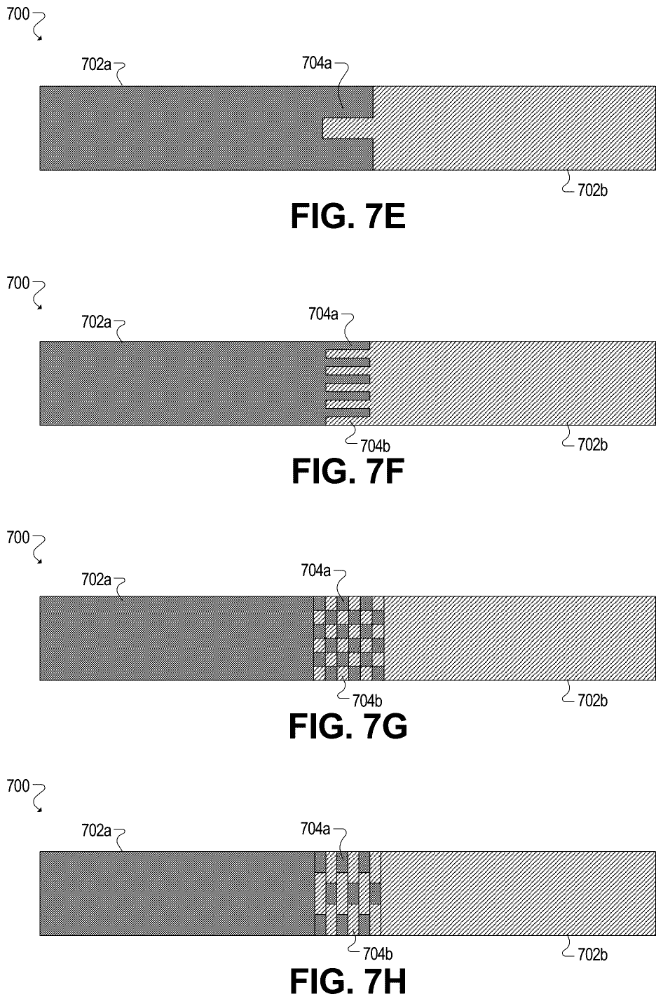

The scope of this approach is not limited to the designs shown in interface 600. Rather, it can be extended to more complex interfaces that provide a highly diffuse boundary between the stitched patterns, within the limitations of the mask process used to create these interfaces. Examples of various patterned line end interfaces are shown in FIG. 7, any of which can be incorporated into interfaces 400, 500, and 600 of FIGS. 4-6.

FIGS. 7A-H illustrate various examples of stitched lines 700 with patterned “line end” interfaces. In each example, a stitched line 700 is formed by printing two line portions 702a,b with complementary “line end” patterns 704a,b using different reticles in adjacent fields on a wafer. For example, the complementary “line end” patterns 704a,b may include tapered/angled edge patterns, point/arrowhead patterns, stair step/puzzle piece patterns, keyhole patterns, alternating/interleaving line patterns, interleaving checkerboard patterns, and so forth. These patterned line ends can be used to create more complex and diffuse interfaces for stitched lines, which can be incorporated into the patterns of lines and rungs in the guard ring designs described throughout this disclosure.

These stitched lines are more robust to changes in their dimensions due to placement errors between their respective patterns, which makes their critical dimensions more resilient to overlay errors. For example, since each reticle has a certain placement and/or distortion error, the combined error of multiple reticles can result in a gap or overlap between the stitched patterns. Notably, absent the overlapping line end designs discussed herein (e.g., butting two straight-edged line portions together), the gap or overlap causes a depletion or excess of photoacids generated, respectively. Depletion in photoacids can result in a decrease in critical dimensions or, in extreme cases, resist bridging or resist scum. An excess of photoacids can cause an undesirable bulge in critical dimensions.

The line end designs disclosed herein eliminate or minimize variations in photoacid concentrations due to registration mismatch and/or distortion error between stitched reticle fields. For example, the discussed interface designs provide desirable perturbations in the concentration of the generated photoacid concentrations that are spread out over a larger interface area to minimize the variations in the regions of overlap of the resultant stitched line features even when a registration mismatch and/or distortion errors are present.

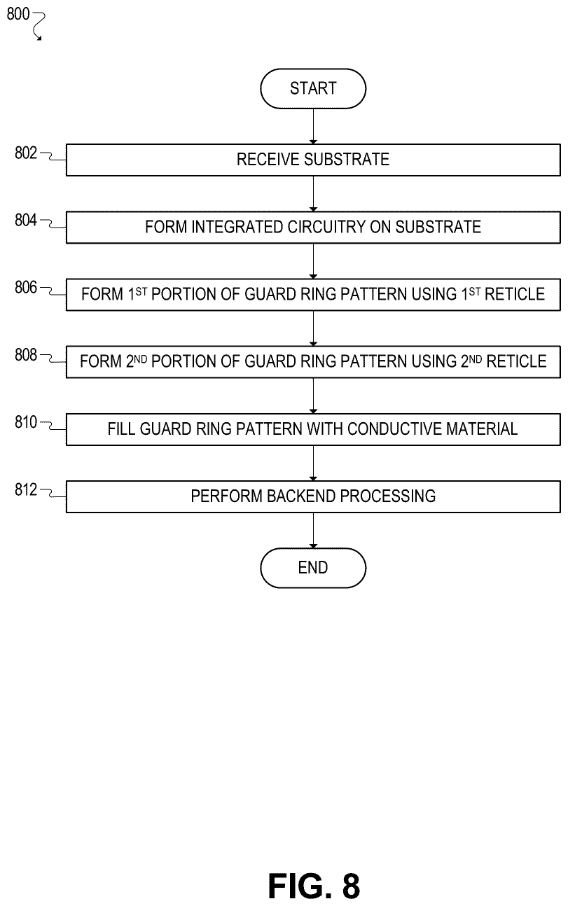

FIG. 8 illustrates a flowchart 800 for fabricating integrated circuits with stitched guard rings in accordance with certain embodiments. It will be appreciated in light of the present disclosure that flowchart 800 is only one example methodology for forming integrated circuits with the guard ring embodiments described herein.

The steps of flowchart 800 may be performed using any suitable semiconductor fabrication techniques. For example, patterning and removal steps may be performed using any suitable techniques, such as lithography-based patterning/masking and/or etching. Moreover, film deposition-such as depositing layers, filling portions of or openings in layers (e.g., removed portions)—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD).

The flowchart begins at block 802, where a substrate (e.g., a wafer) is received for processing. The substrate may include any suitable substrate material. For example, the substrate may include a semiconductor material such as monocrystalline silicon (Si), germanium (Ge), silicon germanium (SiGe), a III-V materials based material (e.g., gallium arsenide (GaAs)), a silicon carbide (SiC), a sapphire (Al₂O₃), or any combination thereof. Further, the substrate may be coated with a photoresist layer for patterning operations. The photoresist layer may include any suitable photoresist, such as a positive photoresist material.

The flowchart then proceeds to block 804 to form integrated circuitry on the substrate (e.g., processing circuitry, memory circuitry, communication circuitry, interconnect circuitry). For example, one or more device layers and one or more metallization layers may be formed on the substrate to form the appropriate circuitry. The device layers may include transistors, memory devices, capacitors, resistors, optoelectronic devices, switches, or any other active or passive electronic devices, or portions thereof. The metallization layers may include via layers and metal line layers to interconnect and provide access to the devices.

The flowchart then proceeds to block 806 to form a first portion of a stitched guard ring using a first reticle. The first reticle may be patterned with the first portion of the guard ring. For example, the first reticle may include a pattern of lines and rungs, where the lines extend partially around a first portion of the integrated circuitry area, and the rungs extend crosswise between (e.g., across) at least some of the lines (e.g., in the stitch zone). Moreover, the first reticle may be used to print the first portion of the guard ring on the underlying substrate layers using photolithography techniques, forming a trench having the same pattern as the first reticle.

The flowchart then proceeds to block 808 to form a second portion of a guard ring pattern using a second reticle. The second reticle may be patterned with the second portion of the guard ring. For example, the second reticle may include a pattern of lines and rungs, where the lines extend partially around a second portion of the integrated circuitry area, and the rungs extend crosswise between (e.g., across) at least some of the lines (e.g., in the stitch zone). Moreover, the second reticle may be used to print the second portion of the guard ring on the underlying substrate layers using photolithography techniques, forming a trench having the same pattern as the second reticle.

In this manner, the trenches formed by the respective reticles have the combined pattern of both reticles.

The flowchart then proceeds to block 810 to fill both portions of the guard ring with a conductive material to form a completed guard ring around the integrated circuitry. For example, the trenches formed by the respective reticles may be filled with a metal, such as copper, manganese, titanium, gold, silver, palladium, nickel, aluminum, tantalum, cobalt, iron, and/or alloys thereof.

The filled trenches form traces, which are collectively arranged in the combined pattern of the two reticles used to print the trench patterns. For example, the traces may be arranged in a pattern of lines and rungs, where the lines extend around the integrated circuitry, and the rungs extend crosswise between (e.g., across) at least some of the lines. In some embodiments, the lines may be substantially parallel to each other, and the rungs may be substantially orthogonal to the lines. Further, the rungs may be positioned in the stitch zone of the guard ring.

In some embodiments, at least some of the rungs may overlap at least partially with some of the lines. Further, at least some of the rungs may have a patterned interface with at least some of the lines, where the patterned interface is formed by complementary patterns that interface with each other. Similarly, at least some of the lines may have a patterned interface in the stitch zone of the guard ring (e.g., with complementary patterns that interface with each other).

In some embodiments, the completed guard ring may extend along the entire perimeter of the substrate. The guard ring may have any suitable shape, including a substantially rectangular, square, or circular shape. Moreover, because the guard ring is stitched across two or more adjacent reticle fields, the completed guard ring may have a size that is larger than 26 millimeters by 33 millimeters, which is the maximum field size for some lithography systems.

The flowchart then proceeds to block 812 to perform the remaining backend processing to complete the integrated circuitry. For example, the wafer may subsequently be singulated into semiconductor dies, and each semiconductor die may then be packaged with other components. For example, each semiconductor die may be electrically coupled to a package substrate, and the package substrate may be electrically coupled to another substrate, such as a printed circuit board and/or another integrated circuit package. In some embodiments, the resulting integrated circuit package may be incorporated into an electronic device (e.g., a cell phone, a wearable device, a computer, a server, a camera, a video playback device, a video game console, a display device, a vehicle control unit, or an appliance).

At this point, the flowchart may be complete. In some embodiments, however, the flowchart may restart and/or certain blocks may be repeated. For example, in some embodiments, the flowchart may restart at block 802 to continue fabricating integrated circuits with stitched guard rings.

### Example Integrated Circuit Embodiments

FIG. 9 is a cross-sectional side view of an integrated circuit device 900 that may be included in any of the embodiments disclosed herein (e.g., in any of the dies). One or more of the integrated circuit devices 900 may be included in one or more dies (e.g., dies 102, 200 of FIGS. 1-2). The integrated circuit device 900 may be formed on a die substrate 902 (e.g., wafer 100 of FIG. 1) and may be included in a die (e.g., die 102, 200 of FIGS. 1-2). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., die 102, 200 of FIGS. 1-2) or a wafer (e.g., the wafer 100 of FIG. 1).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components. The conductive contacts 936 may serve as any of the conductive contacts described throughout this disclosure.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936. These additional conductive contacts may serve as any of the conductive contacts described throughout this disclosure.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. These additional conductive contacts may serve as any of the conductive contacts described throughout this disclosure. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

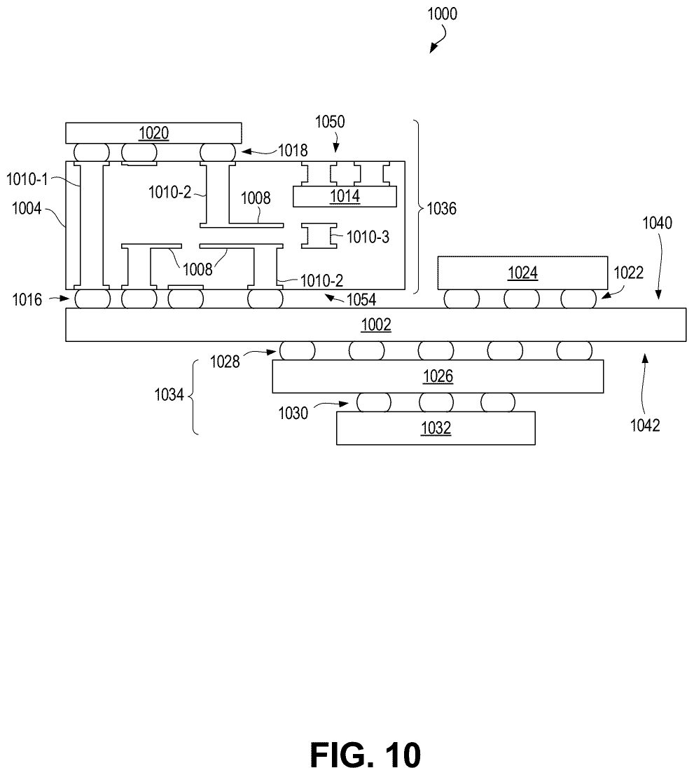

FIG. 10 is a cross-sectional side view of an integrated circuit device assembly 1000 that may include any of the embodiments disclosed herein. For example, any of the components of assembly 1000, such as circuit board 1002, interposer 1004, and integrated circuit components 1020, 1024, 1026, 1032, may include one or more stitched guard rings according to the embodiments disclosed herein.

In some embodiments, the integrated circuit device assembly 1000 may be a microelectronic assembly. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042. Any of the integrated circuit components discussed below with reference to the integrated circuit device assembly 1000 may take the form of any suitable ones of the embodiments of the microelectronic assemblies disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1016 may serve as the coupling components illustrated or described for any of the substrate assembly or substrate assembly components described herein, as appropriate.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpacked integrated circuit product that includes one or more integrated circuit dies (e.g., die 102 of FIG. 1, integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

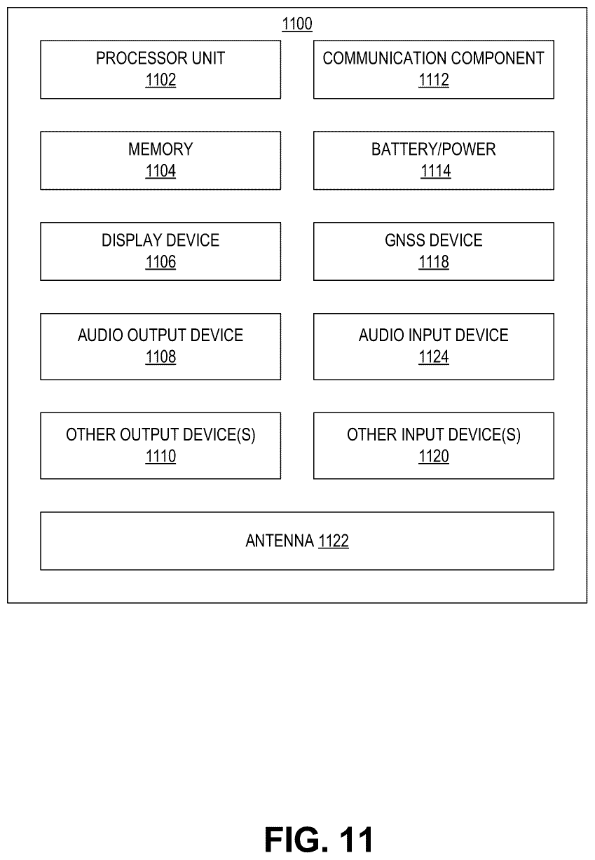

FIG. 11 is a block diagram of an example electrical device 1100 that may include one or more of the embodiments disclosed herein. For example, any of the components of the electrical device 1100 (e.g., processing circuitry 1102, memory circuitry 1104, communication circuitry 1112) may include one or more stitched guard rings on one or more integrated circuit dies 102, integrated circuit device assemblies 1000, integrated circuit components 1020, or integrated circuit devices 900 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include other output device(s) 1110 (or corresponding interface circuitry, as discussed above). Examples of the other output device(s) 1110 may include an audio codec, a video codec, a printer, a wired or wireless transmitter for providing information to other devices, or an additional storage device.

The electrical device 1100 may include other input device(s) 1120 (or corresponding interface circuitry, as discussed above). Examples of the other input device(s) 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

### Example Embodiments

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.
Example 1 includes a semiconductor die, comprising: a substrate comprising integrated circuitry; and a guard ring surrounding the integrated circuitry, wherein the guard ring comprises a plurality of traces arranged in a pattern of lines and rungs, wherein the lines extend around the integrated circuitry, and wherein the rungs extend crosswise between at least some of the lines.
Example 2 includes the semiconductor die of Example 1, wherein: the lines are substantially parallel to each other; and the rungs are substantially orthogonal to the lines.
Example 3 includes the semiconductor die of any of Examples 1-2, wherein the rungs are positioned in a stitch zone of the guard ring.
Example 4 includes the semiconductor die of any of Examples 1-3, wherein at least some of the rungs overlap at least partially with some of the lines.
Example 5 includes the semiconductor die of Example 4, wherein at least some of the rungs have a patterned interface with at least some of the lines, wherein the patterned interface comprises complementary patterns that interface with each other.
Example 6 includes the semiconductor die of any of Examples 1-5, wherein at least some of the lines have a patterned interface in a stitch zone of the guard ring, wherein the patterned interface comprises complementary patterns that interface with each other.
Example 7 includes the semiconductor die of any of Examples 1-6, wherein the guard ring extends along a perimeter of the substrate.
Example 8 includes the semiconductor die of any of Examples 1-7, wherein the guard ring has a substantially rectangular or square shape.
Example 9 includes the semiconductor die of any of Examples 1-8, wherein the guard ring has a size larger than 26 millimeters by 33 millimeters.
Example 10 includes the semiconductor die of any of Examples 1-9, wherein the guard ring is a hermetic guard ring, wherein the hermetic guard ring is in contact with the substrate.
Example 11 includes the semiconductor die of any of Examples 1-10, wherein the plurality of traces comprise metal.
Example 12 includes the semiconductor die of Example 11, wherein the metal comprises copper, manganese, titanium, gold, silver, palladium, nickel, aluminum, tantalum, cobalt, or iron.
Example 13 includes the semiconductor die of any of Examples 1-12, wherein the semiconductor die is electrically coupled to a package substrate.
Example 14 includes an electronic device, comprising: a circuit board; and an integrated circuit electrically coupled to the circuit board, wherein the integrated circuit comprises: a substrate; integrated circuitry on the substrate; and a guard ring surrounding the integrated circuitry, wherein the guard ring comprises a plurality of traces arranged in a pattern of lines and rungs, wherein the lines extend around the integrated circuitry, and wherein the rungs extend across at least some of the lines.
Example 15 includes the electronic device of Example 14, wherein: the lines are substantially parallel to each other; and the rungs are substantially orthogonal to the lines.
Example 16 includes the electronic device of any of Examples 14-15, wherein the rungs are positioned in a stitch zone of the guard ring.
Example 17 includes the electronic device of any of Examples 14-16, wherein the integrated circuitry comprises processing circuitry, memory circuitry, or communication circuitry.
Example 18 includes a method, comprising: forming integrated circuitry on a substrate; forming a first portion of a guard ring in a first location over the substrate using a first reticle, wherein the first reticle comprises a first pattern of lines and rungs, wherein the lines in the first pattern form a first portion of an enclosure around the integrated circuitry, and wherein the rungs in the first pattern extend across at least some of the lines in the first pattern; forming a second portion of the guard ring in a second location over the substrate using a second reticle, wherein the second reticle comprises a second pattern of lines and rungs, wherein the lines in the second pattern form a second portion of the enclosure around the integrated circuitry, and wherein the rungs in the second pattern extend across at least some of the lines in the second pattern; and filling the first portion and the second portion of the guard ring with a conductive material.
Example 19 includes the method of Example 18, wherein forming the integrated circuitry on the substrate comprises: forming one or more first layers of semiconductor devices on the substrate; and forming one or more second layers of conductive traces on the substrate.
Example 20 includes the method of any of Examples 18-19, wherein: forming the first portion of the guard ring in the first location over the substrate using the first reticle comprises: forming, in the first location over the substrate, a first trench having the first pattern of lines and rungs from the first reticle; forming the second portion of the guard ring in the second location over the substrate using the second reticle comprises: forming, in the second location over the substrate, a second trench having the second pattern of lines and rungs from the second reticle.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for case of understanding and may vary by some margin of error in actual embodiments (e.g., due to fabrication processes, etc.).

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “layer” may refer to one or more structures formed using the same reticle and/or during the same processing step of a semiconductor fabrication process.

The term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

1. A semiconductor die, comprising:
a substrate comprising integrated circuitry; and
a guard ring surrounding the integrated circuitry, wherein the guard ring comprises a plurality of traces arranged in a pattern of lines and rungs, wherein the lines extend around the integrated circuitry, and wherein the rungs extend crosswise between at least some of the lines.

2. The semiconductor die of claim 1, wherein:
the lines are substantially parallel to each other; and
the rungs are substantially orthogonal to the lines.

3. The semiconductor die of claim 1, wherein the rungs are positioned in a stitch zone of the guard ring.

4. The semiconductor die of claim 1, wherein at least some of the rungs overlap at least partially with some of the lines.

5. The semiconductor die of claim 4, wherein at least some of the rungs have a patterned interface with at least some of the lines, wherein the patterned interface comprises complementary patterns that interface with each other.

6. The semiconductor die of claim 1, wherein at least some of the lines have a patterned interface in a stitch zone of the guard ring, wherein the patterned interface comprises complementary patterns that interface with each other.

7. The semiconductor die of claim 1, wherein the guard ring extends along a perimeter of the substrate.

8. The semiconductor die of claim 1, wherein the guard ring has a substantially rectangular or square shape.

9. The semiconductor die of claim 1, wherein the guard ring has a size larger than 26 millimeters by 33 millimeters.

10. The semiconductor die of claim 1, wherein the guard ring is a hermetic guard ring, wherein the hermetic guard ring is in contact with the substrate.

11. The semiconductor die of claim 1, wherein the plurality of traces comprise metal.

12. The semiconductor die of claim 11, wherein the metal comprises copper, manganese, titanium, gold, silver, palladium, nickel, aluminum, tantalum, cobalt, or iron.

13. The semiconductor die of claim 1, wherein the semiconductor die is electrically coupled to a package substrate.

14. An electronic device, comprising:
a circuit board; and
an integrated circuit electrically coupled to the circuit board, wherein the integrated circuit comprises:
a substrate;
integrated circuitry on the substrate; and
a guard ring surrounding the integrated circuitry, wherein the guard ring comprises a plurality of traces arranged in a pattern of lines and rungs, wherein the lines extend around the integrated circuitry, and wherein the rungs extend across at least some of the lines.

15. The electronic device of claim 14, wherein:
the lines are substantially parallel to each other; and
the rungs are substantially orthogonal to the lines.

16. The electronic device of claim 14, wherein the rungs are positioned in a stitch zone of the guard ring.

17. The electronic device of claim 14, wherein the integrated circuitry comprises processing circuitry, memory circuitry, or communication circuitry.

18. A method, comprising:
forming integrated circuitry on a substrate;
forming a first portion of a guard ring in a first location over the substrate using a first reticle, wherein the first reticle comprises a first pattern of lines and rungs, wherein the lines in the first pattern form a first portion of an enclosure around the integrated circuitry, and wherein the rungs in the first pattern extend across at least some of the lines in the first pattern;
forming a second portion of the guard ring in a second location over the substrate using a second reticle, wherein the second reticle comprises a second pattern of lines and rungs, wherein the lines in the second pattern form a second portion of the enclosure around the integrated circuitry, and wherein the rungs in the second pattern extend across at least some of the lines in the second pattern; and
filling the first portion and the second portion of the guard ring with a conductive material.

19. The method of claim 18, wherein forming the integrated circuitry on the substrate comprises:
forming one or more first layers of semiconductor devices on the substrate; and
forming one or more second layers of conductive traces on the substrate.

20. The method of claim 18, wherein:
forming the first portion of the guard ring in the first location over the substrate using the first reticle comprises:
forming, in the first location over the substrate, a first trench having the first pattern of lines and rungs from the first reticle; and
forming the second portion of the guard ring in the second location over the substrate using the second reticle comprises:
forming, in the second location over the substrate, a second trench having the second pattern of lines and rungs from the second reticle.
